(19) United States
(12) Patent Application Publication
(10) Pub. No.: US 2022/0298633 A1
(43) Pub. Date: Sep. 22, 2022

(54) METHOD OF CONTROLLING AN AMOUNT OF SOLUBLE BASE CONTENT OF MATERIAL COMPRISING LITHIUM CARBONATE AND STRUCTURE, CATHODE, AND BATTERY FORMED USING THE METHOD

(71) Applicant: The Regents of the University of Colorado, a body corporate, Denver, CO (US)

(72) Inventors: Alan D. Weimer, Niwot, CO (US); William McNeary, Boulder, CO (US)

(21) Appl. No.: 17/619,579

(22) PCT Filed: Jun. 16, 2020
(86) PCT No.: PCT/US2020/037901

§ 371 Date: Dec. 15, 2021

Related U.S. Application Data
(60) Provisional application No. 62/862,093, filed on Jun. 16, 2019.

(51) Int. Cl. C23C 16/455; C23C 16/52; H01M 4/505; C23C 16/04; C23C 16/40; H01M 4/525; H01M 10/0525; H01M 4/04

(52) U.S. Cl. CPC C23C 16/45527; C23C 16/52; H01M 4/505; C23C 16/45555; C23C 16/04; C23C 16/409; C23C 16/406; H01M 4/525; H01M 10/0525; H01M 4/0428; H01M 2004/028

(57) ABSTRACT

Methods of controlling an amount of soluble base content of material comprising lithium carbonate and other material. Exemplary methods include using atomic layer deposition, selectively depositing one or more of an oxide, a fluoride, and a nitride to form and/or control the soluble base content.

### CROSS REFERENCE TO RELATED APPLICATION

This application claims the benefit of U.S. Provisional Patent Application Ser. No. 62/862,093, filed Jun. 16, 2019, entitled METHOD OF CONTROLLING AN AMOUNT OF SOLUBLE BASE CONTENT OF MATERIAL COMPRISING LITHIUM CARBONATE AND STRUCTURE, CATHODE, AND BATTERY FORMED USING THE METHOD, the contents of which are hereby incorporated herein by reference to the extent such contents do not conflict with the present disclosure.

### BACKGROUND OF THE DISCLOSURE

Lithium ion batteries have many desirable properties, including relatively high energy density and relatively low self-discharge. However, capacity fading, voltage decay and low rate capability are observed upon cycling of many lithium ion batteries. These failures are thought to stem from dissolution of metals into liquid electrolytes and structural instability of cathode materials caused by lattice strain induced by lithium ion intercalation upon each discharge.

Surface impurity species formed on cathode active materials of lithium ion batteries can lead to a delithiation voltage peak in the first charge and reduce the cycling stability of battery electrodes. This is particularly significant for nickel-rich lithium nickel manganese cobalt oxide (NMC) electrode materials. Generally, as the nickel content increases in NMC batteries, an amount of lithium that can be cycled in and out of the cathode increases and therefore the energy density increases. Nickel-rich NMC batteries frequently exhibit faster capacity fading and shorter lifetimes compared to standard NMC materials. The high surface reactivity of nickel-rich positive electrodes can lead to the formation of surface impurity species upon reactions with carbon dioxide and water during ambient storage, which can cause problems during electrode slurry preparation, battery storage, and cycling. In general, three processes are thought to be responsible for the presence of surface carbonates and hydroxides: (1) residual impurities stemming from unreacted precursors during synthesis, (2) a higher equilibrium coverage of surface carbonates/hydroxides required to stabilize the surface of Ni-rich materials after the synthesis process, and/or (3) impurities formed during ambient storage. NMC cathode materials can have different amounts of surface carbonates and hydroxides (referred to as the soluble base content (SBC)), which can be dependent on the synthesis conditions such as Li:M ratio, temperature, and reaction time. If Li₂CO₃ or LiOH is used as a Li-source during the synthesis, stoichiometric conversion may be desired (e.g., MOOH+0.5 Li₂CO₃ [symbol] LiMO₂+0.5 CO₂+0.5 H₂O having M=Ni, Co, Mn) as otherwise residual Li₂CO₃ or LiOH precursor would remain on the NMC particle surfaces. When Li₂CO₃ is quantitatively converted, only a low soluble base content (SBC) may be present on the NMC surface.

Although one might expect that an NMC without any carbonates or hydroxides on the surface may be ideal, a desired SBC may be different from zero, and may be referred to as equilibrium SBC. This equilibrium SBC is proposed to be a surface termination which is desired to stabilize the surface of the material and to allow for good cyclability, rather than being a detrimental surface impurity. NMC batteries with an SBC below the desired SBC equilibrium value may have poor electrochemical performance. On the other hand, too high of SBC can cause gelation or flocculation during slurry preparation and extensive gassing during high temperature storage of charged battery cells. It has recently been reported that the majority of the impurities formed may be carbonates with minor fractions of hydroxides and water.

In view of the foregoing, it may be desirable to be able to control the SBC in NCM materials (e.g., near the equilibrium value), to thereby enable tuning or optimizing the SBC, so that initial discharge capacity and cycling stability are maintained and/or to improve other battery performance.

Any discussion of problems and solutions involved in the related art has been included in this disclosure solely for the purposes of providing a context for the present invention and should not be taken as an admission that any or all of the discussion was known at the time the invention was made.

### SUMMARY OF THE DISCLOSURE

Various embodiments of the present disclosure relate to methods of forming lithium ion battery cathode material having improved properties and to improved cathodes, cells, and batteries with the improved cathode material. While the ways in which various embodiments of the present disclosure address drawbacks of prior techniques are discussed in more detail below, in general, various embodiments of the disclosure provide improved methods suitable for controlling and tuning an amount of soluble base content of lithium ion battery cathode material.

In accordance with various examples of the disclosure, a method of controlling an amount of soluble base content of material comprising lithium carbonate and other material includes providing the material within a reaction chamber and using cyclical deposition—e.g., atomic layer deposition, selectively depositing one or more of an oxide, a fluoride, and a nitride on the other material compared to the lithium carbonate. During the step of using cyclical deposition, the material can be exposed to more than one and less than ten cycles of atomic layer deposition, more than one and less than six cycles of atomic layer deposition, more than one and less than four cycles of atomic layer deposition, or between two and six cycles of atomic layer deposition. Exemplary methods can include selectively depositing the oxide, wherein the oxide is selected from one or more of the group of transition metal oxides, such as Al₂O₃, MgO, SiO₂, TiO₂, ZnO, SnO₂, ZrO₂, NbO₃, and/or B₂O₃. In accordance with further examples, a lithium metal oxide (e.g., formed from a deposited metal oxide) is formed. The lithium metal oxide (e.g., lithium aluminum oxide (e.g., stoichiometric lithium aluminum oxide)) can form at least part of the SBC. Further examples include selectively depositing the nitride, wherein the nitride is selected from one or more of the group of metal nitrides and metalloid nitrides. Particular exemplary nitrides include boron nitride, BN and tungsten nitride, WN. In these cases, a lithium metal nitride can form at least part of the SBC. In some cases, both an oxide and a nitride can be deposited. For example, more than one and less than six cycles of atomic layer deposition or more than one and less than four cycles of an oxide or nitride can be formed and then more than one and less than six cycles of atomic layer deposition or more than one and less than four cycles of the other of an oxide and nitride can be formed. In some cases, a total number of ALD cycles is less than 10 or less than 6.

Methods in accordance with the disclosure can further include a step of determining an amount of lithium carbonate in the material, wherein a number of cycles of the atomic layer deposition can be determined based on the amount of lithium carbonate in the material. For example, the higher the carbonate concentration, the higher the number of deposition cycles. Various methods may be particularly useful for nickel-rich NMC materials, such as NCM 811 (Li Ni.8 Co.1 Mn.1 O₂; Ni is 48.3 wt %), NCM 523 (Li Ni.5 Co.2 Mn.3 O₂; Ni is 30.4 wt %), and NCM 111 (Li Ni.33 Co.33 Mn.33 O₂; Ni is 20.2 wt %).

In accordance with further embodiments of the disclosure, cathode material is provided. In accordance with examples of these embodiments, the cathode material includes non-uniform (e.g., non-uniform thickness and/or composition) lithium metal (e.g., aluminum) oxide (or nitride or fluoride) that forms as a result of ALD-like deposition of the oxide, fluoride, or nitride. In this context, non-uniform can mean, greater than 30%, greater than 25%, greater than 15%, greater than 10%, or greater than 5%.

In accordance with further examples of the disclosure, a cathode is formed using a method as described herein.

In accordance with further examples of the disclosure, a method of forming a battery is provided.

And, in accordance with yet additional embodiments of the disclosure, a battery including a cathode formed in accordance with the disclosure is provided.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates XPS analysis of NCM materials, including residual LiOH and Li₂CO₃, in accordance with examples of the disclosure.

FIGS. 2 and 3 illustrate residual CO₃ detected by XPS of NMC cathode material in accordance with examples of the disclosure.

FIG. 4 illustrates mass spectrometry traces for the first six ALD cycles on LiOH in accordance with examples of the disclosure.

FIG. 5 illustrates mass spectrometry traces for the first six ALD cycles on Li₂CO₃ in accordance with examples of the disclosure.

FIG. 6 illustrates calculated TMA breakthrough times in accordance with examples of the disclosure.

FIG. 7 illustrates ICP results for aluminum content on substrates at various ALD cycles in accordance with examples of the disclosure.

FIG. 8 illustrates comparative, area-normalized weight percent aluminum deposited on LiOH, Li₂CO₃, and NMC111.

FIG. 9 illustrates a cathode or structure formed in accordance with examples of the disclosure.

FIG. 10 illustrates a battery including a cathode formed in accordance with examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The present disclosure generally relates to methods of controlling an amount of soluble base content (SBC) of material—e.g., cathode material of, e.g., lithium-ion electrochemical cells and batteries; to methods of forming cathodes; to methods of forming batteries; and to cathodes and batteries formed using the methods. The SBC to be controlled can be SBC of material comprising lithium carbonate and other material, such as lithium hydroxide, lithium aluminum oxide, lithium fluoride oxide, lithium boron oxide, lithium aluminum fluoride oxide, lithium aluminum boron oxide, or the like.

Exemplary methods of controlling an amount of SBC material include providing the material within a reaction chamber and, using a cyclical deposition method, such as atomic layer deposition, selectively depositing one or more of an oxide, a fluoride, and a nitride on the other material compared to the lithium carbonate. The other material can be or include lithium hydroxide. After the step of using atomic layer deposition, a surface of the material can include lithium carbonate and/or lithium and one or more of the oxide, the fluoride, the nitride, the boride, a lithium metal (e.g., aluminum) oxide, nitride, boride, or fluoride, a lithium fluoride oxide or nitride, lithium aluminum fluoride oxide or nitride, lithium aluminum boride oxide or nitride, or the like.

The oxide deposited using ALD can be selected from one or more of the group of transition metal oxides, such as a metal oxide selected from the group consisting of Al₂O₃, MgO, SiO₂, TiO₂, ZnO, SnO₂, ZrO₂, NbO₃, and B₂O₃. The nitride can be selected from one or more of the group of metal nitrides and metalloid nitrides. By way of particular examples, the nitride can include one or more of boron nitride or tungsten nitride. During the step of providing the material within a reaction chamber, a material comprising lithiated metal oxide having a general formula of LiMₓO_{y} can be provided. The metal represented by “M” in the lithiated metal oxide can be chosen from at least one of Co, Ni, Mn, Fe, Al, and Ti. Non-limiting examples of the lithiated metal can be chosen from at least one of lithium cobalt oxide (LiCoₓO_{y}), lithium nickel oxide (LiNiₓO_{y}), lithium manganese oxide (LiMnₓO_{y}), lithium nickel cobalt manganese oxide, (LiNiₓCo_{y}Mn_{z}Oz_{z}), lithium nickel cobalt manganese iron oxide (LiNiₓCo_{y}Mn_{z}Fey_{y}Oz_{z}), lithium iron phosphate (LiFeₓPO_{y}), lithium nickel cobalt aluminum oxide (LiNiₓCo_{y}Al_{z}Oz_{z}), and lithium titanate (LiTiₓO_{y}). Lithium nickel cobalt manganese oxide (LiNiₓCo_{y}Mn_{z}Oz_{z}) is also referred to herein as “NMC.” In some cases, the nickel lithium manganese cobalt oxide material can be represented by a general formula of LiNiₓMn_{y}Co_{z}O₂, where x+y+z can equal 1. In some cases, the nickel lithium manganese cobalt oxide can be nickel rich. In these cases, the nickel lithium manganese cobalt oxide can include greater than 20.2 wt % nickel or greater than 48.3 wt % nickel. A surface area of the lithiated metal oxide can range from about 0.1 m2/g to about 0.2 m2/g or about 0.5 m2/g to about 5 m2/g.

The reaction chamber can be or include a suitable particle handling system such as a fluidized bed, rotating drum, sequential batch mixer, or vibrating reactor. These systems can provide a desired environment for the particles to interact with the gases and be coated while not aggregating the particles together.

During the step of using atomic layer deposition, one or more of an oxide, a fluoride, and a nitride are selectively deposited on the other material compared to the lithium carbonate. During this step, the material can be exposed to more than one and less than ten or to more than one and less than four or to more than one and less than six of atomic layer deposition cycles. In some cases, exemplary methods further include a step of determining an amount of lithium carbonate in the material. In these cases, a number of cycles of the atomic layer deposition can be determined based on the amount of the lithium carbonate in the material. Additionally or alternatively, a number of atomic layer deposition cycles can be based on one or more of an amount of lithium hydroxide in the material, an amount of nickel in the material, lithium:metal content in the material, a temperature used to form the material, a temperature during the atomic layer deposition, precursor flowrates during the atomic layer deposition, a precursor pulse time, pressure within the reaction chamber during the atomic layer deposition, and the precursors used during the atomic layer deposition.

Atomic layer deposition (ALD) has been identified as a coating methodology to modify cathode surfaces by exploiting the conformal and pinhole-free nature of ALD films deposited using a sufficient number of ALD cycles. ALD is a gas phase deposition method that is generally performed using repeated cycles of alternating exposures of the substrate surface to one or more precursors that are generally followed by purges of unreacted precursor and any ALD byproducts. Typically, each precursor reacts with surface reactive functional groups resulting in a half-reaction of the overall chemistry. Precursors typically do not self-react, but rather only react with the functionalized surface produced by reaction with, e.g., the complementary precursor. Consequently, the deposition produced by each half-reaction can proceed until no remaining active sites on the substrate surface are accessible to the precursor, making the deposition self-limiting. ALD can be carried out under various operating temperatures, pressures, precursor dose times, and reactor configurations.

In accordance with embodiments of the disclosure, ALD is used to deposit ultra-thin coating technology for modifying NCM and other cathode material surface properties. ALD films are often used to deposit continuous films over the entire surface given sufficient ALD cycle numbers.

When using ALD to coat materials used in electrochemical cells and batteries (e.g., for use in cathode active material), choice of coating material can be important, because preferred coatings may desirably maintain the bulk capacity of the electrode, be conductive to Li ions and electrons, and be chemically resistant to degradation in the electrolyte environment. In some cases, coating thickness can be sub-2 nm or deposited with less than ˜10 cycles of ALD. Due to the ultrathin and incomplete nature of low cycle number ALD films, the coatings can withstand larger strains and thus be less likely to mechanically fail from the repeated cycle of lattice expansions and contractions caused by lithium intercalation and deintercalation. Oxide, nitride, and fluoride coatings, such as alumina ALD films, have shown improved surface structural stability and chemical durability. And, depositions of less than six ALD cycles are thought to be particularly beneficial. Coated LiCoO₂ powders can exhibit a capacity retention of 89% after a 120 V charge—discharge cycles in the 3.3-4.5 V (vs. Li/Li+) range. In contrast, the bare LiCoO₂ powders retained only 45% of their initial capacity. Initial reversible capacity decreased significantly at six ALD cycles and was negligible (˜20 mAh/g) after the 10^{th} ALD cycle. The initial capacity loss before battery cycling was attributed to the large overpotential required for LiCoO₂ powders coated with more than six ALD cycles. The electrically insulating nature of alumina resulted in a reduction of the electronic conductivity as the film thickness increased. It was thought that ALD produces ultrathin uniform films that stabilize the metal oxide structure by preventing contact with the electrolyte. Further, it was thought that the ultrathin nature of ALD facilitates diffusion of lithium through the protective films and, because of this, does not result in a significant capacity loss.

In accordance with examples of the disclosure, precursors and reactants used during the atomic layer deposition step can include one or more of trimethylaluminum(TMA) and water, boron trichloride and ammonia, lithium tert-butoxide (LiOtBut) and hexafluoroacetylacetone (Hfac) or titanium fluoride(TiF₄). A pressure within a reaction chamber during the ALD step can range from about 1 Torr to about 10 torr or about 25 Torr to about 760 Torr. A temperature within a reaction chamber during the ALD step can range from about 33° C. to about 77° C. or about 150° C. to about 300° C.

As illustrated in more detail below, during the ALD steps, the reactant may react with material (e.g., lithium hydroxide) on a surface relative to other material (e.g., lithium carbonate). The reaction can form lithium metal (e.g., aluminum) oxide, nitride, boride, or fluoride preferentially on the other material. The lithium metal oxide, nitride, boride, or fluoride that thus forms can form part of the SBC.

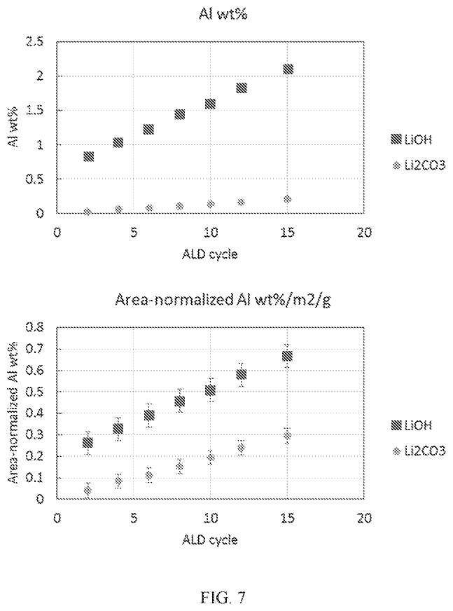

The material (e.g., LiOH) may react non-stoichiometrically at first (offset from zero—illustrated in FIG. 7) with substantial reaction product (e.g., Li—Al-oxide), while the transition metals (e.g., Ni, Co, Mn) are coated with the ALD deposited material to protect the transition metals from dissolution. In some cases, 2 to 4 or 6 cycles allows enough Li—Al-oxide to be available for Li diffusion and to protect the transition metals in the cathode material, whereas too many ALD cycles may coat lithium metal oxide (e.g., lithium aluminum oxide) with material and thereby prevent or mitigate lithium diffusion through the SBC—thus insulating the NMC powder with deposited material. After initially reacting to form non-stoichiometric lithium metal oxide, the lithium metal oxide may form stoichiometrically over, for example, LiOH to form, for example, stoichiometric amorphous lithium metal (e.g., aluminum) oxide. It is thought that lithium can diffuse through the amorphous lithium metal (e.g. aluminum) oxide and can be present on the surface, thus enhancing cathode performance.

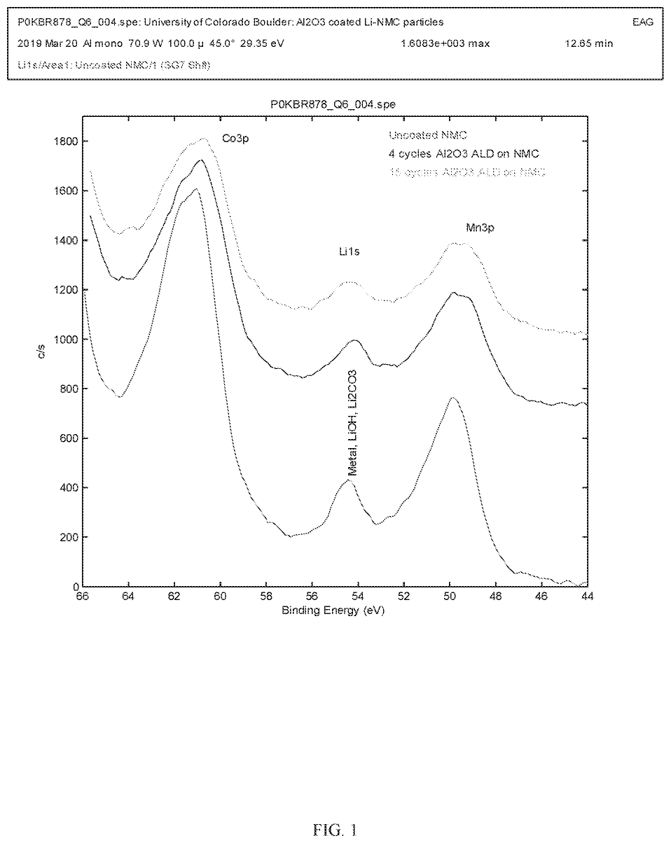

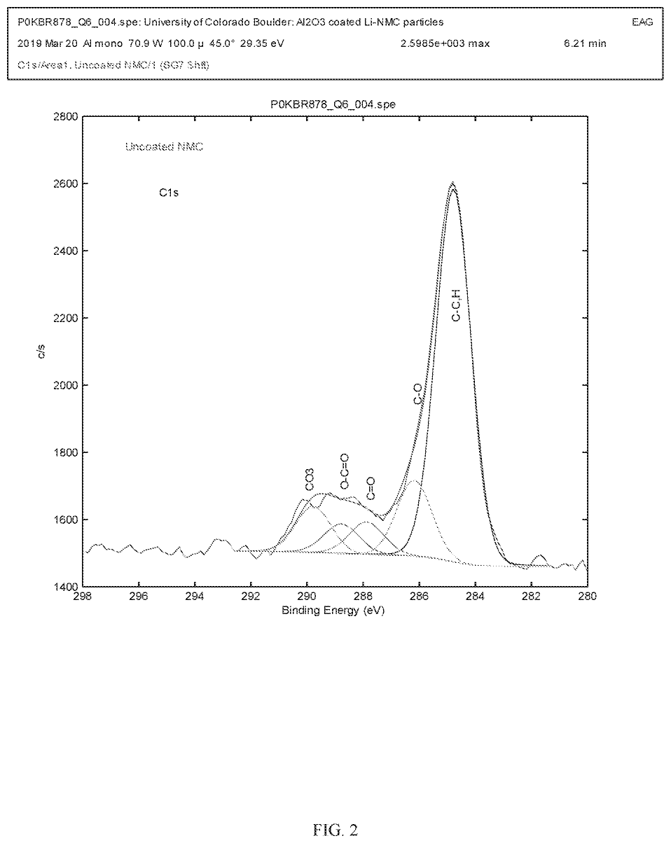

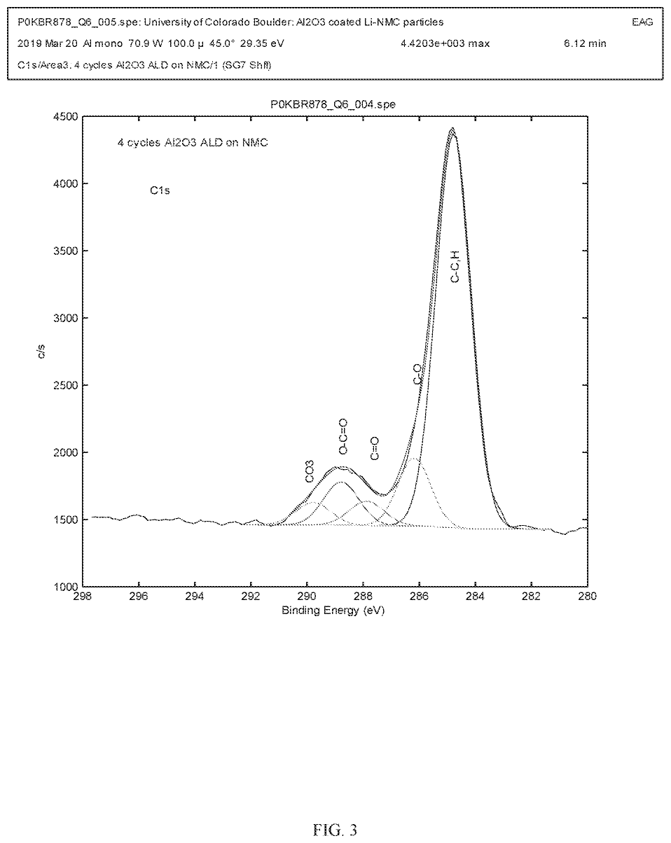

In accordance with examples of the disclosure, as illustrated in FIG. 1, XPS analysis of material formed in accordance with the disclosure shows that NCM materials contain residual LiOH and Li₂CO₃. An amount of residual CO₃ detected by XPS decreased by 50% with four ALD cycles as shown in Table 1 and as illustrated in FIGS. 2 and 3.

TABLE 1
Carbon Chemical States (in % of Total C detected by XPS)

| Sample | C—C, H | C—O | C═O | O—C═O | CO₃ |
|---|---|---|---|---|---|
| Uncoated NMC | 67 | 13 | 6 | 6 | 8 |
| 4 cycles Al₂O₃ | 72 | 12 | 4 | 8 | 4 |
| ALD on NMC | | | | | |

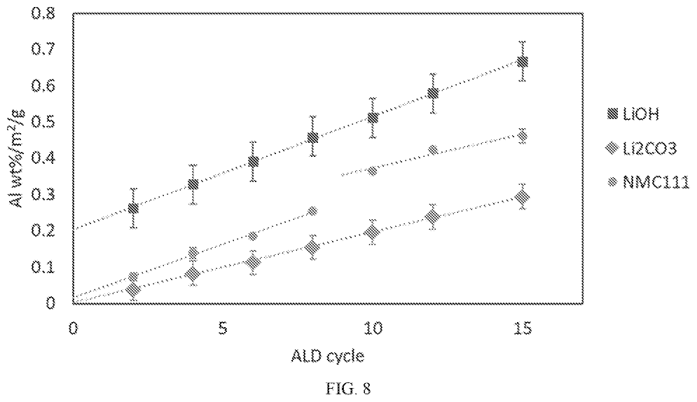

Unexpectedly, ALD coating of Al₂O₃ has been found to have growth rates (g Al/g LiOH or g Li₂CO₃) much faster on LiOH than Li₂CO₃. FIG. 8 illustrates Comparative area-normalized wt % Al for LiOH, Li₂CO₃, and NMC111 for

TMA/H₂O ALD cycling. Aluminum wt % data from ICPMS were normalized by the BET surface area of each uncoated substrate powder. The higher growth rate on LiOH vs Li₂CO₃ indicates that these surfaces behave differently from one another during the Al₂O₃ ALD process, which has implications for the observed Al₂O₃ growth on NMC substrates. It appears that some non-ALD reaction is occurring during the first ˜9 ALD cycles, possibly a reaction forming a Li—Al oxide product, until a typical Al₂O₃ ALD film deposits from 10 to 15 cycles.

In accordance with further examples of the disclosure, cathode active material or cathode material is formed using material formed using a method described herein. By way of examples, a cathode can be formed using about 70 to about 90 or about 80 wt % active materials, about 5 to about 15 or about 10 wt % carbon black (Alfa Aesar), and about 5 to about 15 or about 10 wt % polyvinylidene fluoride (PVDF, Alfa Aesar) mixed with (e.g., nmethyl-2-pyrrolidone (NMP, Sigma-Aldrich)) solvent. The resulting slurry can be conformally cast on an Al foil by a doctor blade or the like. The wet slurry can be dried in air for ˜10 min at 70-80° C. and then placed in a vacuum oven heated at ˜120° C. overnight to remove residual solvent and moisture. The coated foil can then be punched into round discs or other suitable format and calendared at ˜2 t before assembly. The active cathode can vary according to application. Batteries can be assembled in an argon-filled glovebox using the CR2032 coin cell. Lithium metal can be used as the counter-electrode (anode). Between lithium metal and the cathode, a separator (e.g., Celgard-2320) can be used and a LiPF₆ solution (dissolved in EC:DMC=1:1, Sigma-Aldrich) can be used as an electrolyte and filled on both sides of the separator.

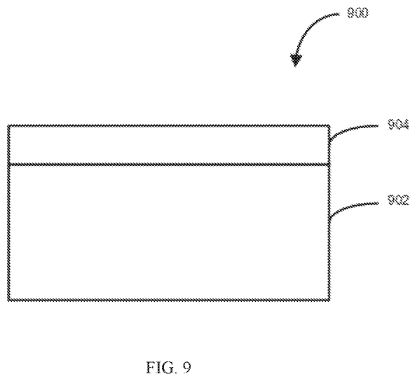

FIG. 9 illustrates a cathode (or structure) 900, including a current collector 902 and cathode active material 904. Cathode active material 904 can be formed using a method—e.g., a method of controlling an amount of soluble base content of material as set forth herein. Current collector 902 can be formed of any suitable material, such as metal.

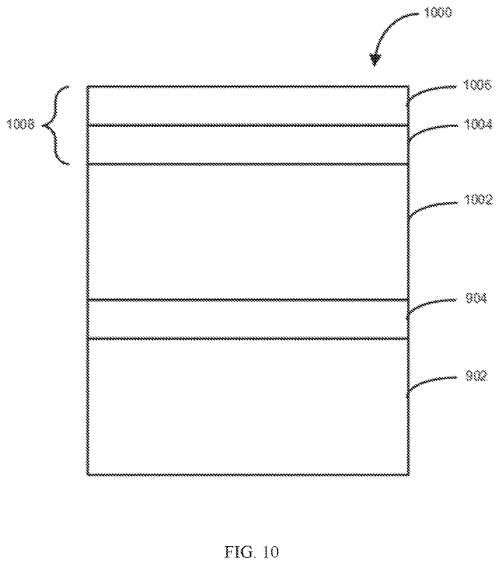

FIG. 10 illustrates a battery 1000 in accordance with additional examples of the disclosure. Battery 1000 includes cathode 900, including current collector 902 and cathode active material 904, a separator 1002, and an anode 1008, including anode active material (e.g., lithium) 1004 and a current collector 1006. Separator 1002 can include a non- conducting material, such as a polymer.

Specific Examples

Atomic layer deposition (ALD) of Al₂O₃ was performed on LiOH (Sigma Aldrich, reagent grade >98) and Li₂CO₃ (Sigma Aldrich, ACS reagent grade >99%) substrates in order to compare rates of growth and amount of material deposited on each substrate. In each set of experiments, 7 g of substrate were initially placed in a fluidized bed reactor operating at 120° C. 1 g of substrate was extracted from the reactor at 2, 4, 6, 8, 10, 12, and 15 ALD cycles. The

ALD process was monitored by in-situ quadrupole mass spectrometry. Following ALD, the materials were analyzed using BET for surface area analysis and ICP-MS to determine elemental content.

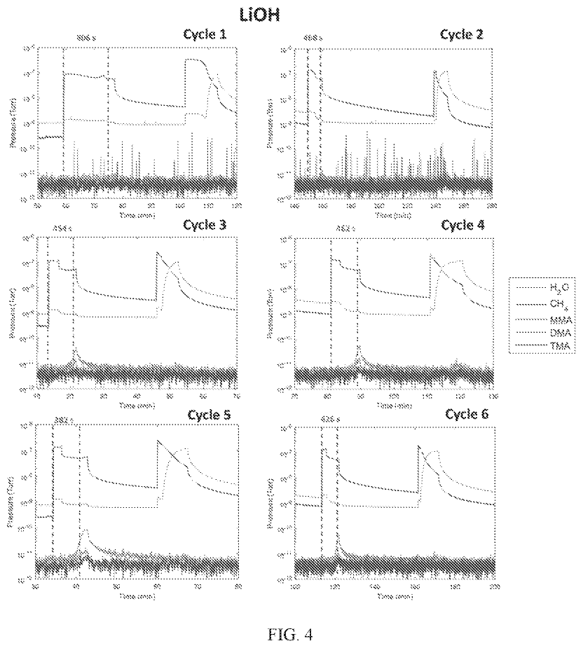

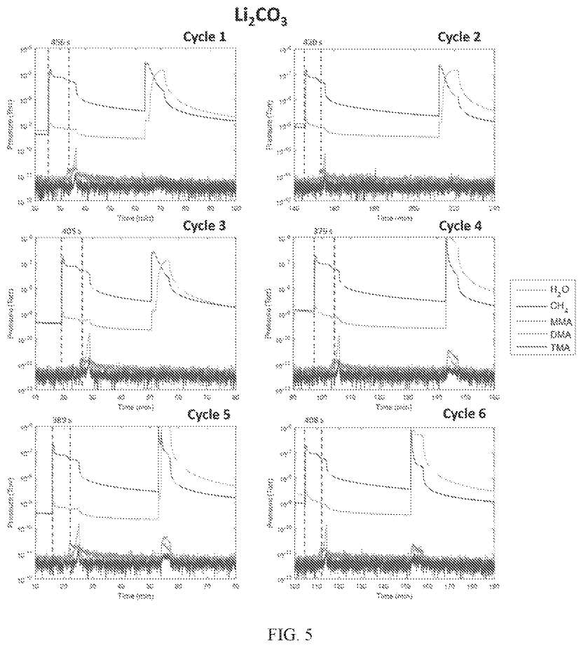

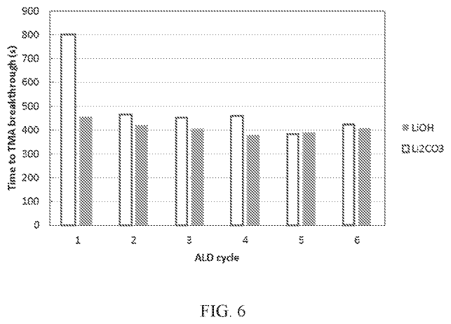

The mass spectrometry traces for the first six ALD cycles on LiOH and Li₂CO₃ are shown in FIGS. 4 and 5. The breakthrough time of the TMA dose in the first half of each of these cycles was calculated in order to qualitatively compare the amount of TMA molecules adsorbing to each surface as the ALD process progressed. The calculated TMA breakthrough times are collected in FIG. 5. Based solely on its longer TMA breakthrough times, LiOH is a more active substrate for Al₂O₃ deposition.

ICP results for Al content on each substrate at various ALD cycles are shown in FIG.7. The results are expressed both as Al wt % and Al wt % normalized by the BET surface area of the uncoated substrate. In the case of Al wt %, the growth rate of Al₂O₃ was considerably higher on LiOH than it was on Li₂CO₃. When normalized by the initial substrate surface area (3.175 m²/g for LiOH and 0.7128 m²/g for Li₂CO₃), the difference in growth rates was not as substantial, indicating that the higher surface area of LiOH may have accounted for some of the enhanced growth; however, area-normalized Al wt % data still showed a slightly higher growth rate on LiOH. Altogether, these data clearly demonstrate that LiOH is innately a more active substrate towards Al₂O₃ ALD than Li₂CO₃.

Hence, it is possible to functionalize the surface of cathode active materials by coating the particle surface using ALD which can coat transition metals, i.e., Ni, Mn, Co, LiOH, and Li2CO3, while leaving some Li exposed in order to achieve the optimal equilibrium SBC. The surface composition will be almost entirely coating (e.g., Al₂O₃) and Li—Al-oxide.

The present invention has been described above with reference to a number of exemplary embodiments and examples. It should be appreciated that the particular embodiments shown and described herein are illustrative of the preferred embodiments of the invention and its best mode, and are not intended to limit the scope of the invention.

Further examples of the disclosure are set forth in the claims. It will be recognized that changes and modifications may be made to the embodiments described herein without departing from the scope of the present invention. These and other changes or modifications are intended to be included within the scope of the present invention.

1. A method of controlling an amount of soluble base content of a material, the material comprising lithium carbonate, and lithium hydroxide and a lithiated metal oxide, the method comprising the steps of:
providing the material within a reaction chamber, the material comprising a surface comprising the lithium carbonate and lithium hydroxide; and
using atomic layer deposition, selectively depositing one or more of an oxide, a fluoride, and a nitride on the other material compared to the lithium carbonate, wherein, during the step of using atomic layer deposition, the material is exposed to more than one and less than ten cycles of atomic layer deposition.

2. The method of claim 1, comprising selectively depositing the oxide, wherein the oxide is selected from one or more of the group of transition metal oxides.

3. The method of claim 2, wherein the oxide is selected from the group consisting of Al₂O₃, MgO, SiO₂, TiO₂, ZnO, SnO₂, ZrO₂, NbO₃, and B₂O_{3.}

4. The method of claim 1, comprising selectively depositing the nitride, wherein the nitride is selected from one or more of the group of metal nitrides and metalloid nitrides.

5. The method of claim 1, wherein the material is exposed to more than one and less than six cycles of atomic layer deposition.

6. The method of claim 1, wherein the material is exposed to more than one and less than four cycles of atomic layer deposition.

7. The method of claim 1, further comprising a step of determining an amount of lithium carbonate in the material by XPS.

8. The method of claim 7, wherein a number of cycles of the atomic layer deposition is determined based on the amount of the lithium carbonate in the material.

9. The method of claim 1, wherein the other material comprises lithium hydroxide.

10. The method of claims 1 and 9, comprising selectively depositing the oxide, wherein the oxide is aluminum oxide, wherein, prior to the step of atomic layer deposition the material comprises lithium hydroxide and lithium carbonate in a first ratio, and after the step of atomic layer deposition the material comprises lithium hydroxide and lithium carbonate in a second ratio, wherein the first ratio is larger than the second ratio.

11. The method of claim 10, wherein after the step of using atomic layer deposition, a surface of the material comprises lithium carbonate and Li—Al-oxide.

12. The method of claim 1, wherein the material comprises nickel-rich lithium manganese cobalt oxide.

13. The method of claim 12, wherein the nickel-rich lithium manganese cobalt oxide comprises greater than 20.2 wt % nickel.

14. The method of claim 1, wherein a number of atomic layer deposition cycles is based on one or more of an amount of nickel in the material, lithium:metal content in the material, a temperature used to form the material, a temperature during the atomic layer deposition, precursor flowrates during the atomic layer deposition, a precursor pulse time, pressure within the reaction chamber during the atomic layer deposition, and the precursors used during the atomic layer deposition.

15. A method of forming cathode material using the method of any of claims 1-14.

16. A cathode formed according to any of the methods of claims 1-15.

17. The cathode of claim 16, wherein the material comprises lithium manganese cobalt oxide.

18. The cathode of claim 17, wherein the material comprises nickel.

19. The cathode of claim 18, wherein the material comprises greater than about 20.2 wt % nickel.

20. A method of forming a battery according to any of claims 1-15.

21. A battery comprising the cathode of any of claims 16-19.

22. The method of any of claims 1-15 wherein the material is in the form of particles and the reaction chamber is a fluidized bed, rotating drum, sequential batch mixer, or vibrating reactor.

23. The method of any of claims 1-6 wherein the material comprises an NCM cathode material and the amount of CO₃ decreases by 50% or less after the step of atomic layer deposition.

24. A method of making a battery comprising the method of claim 23.

25. A battery made by the method of claim 24 wherein the battery comprises the NCM cathode material that has an amount of CO₃ that is no less than 50% that of the material before the step of atomic layer deposition.
